(19) United States
(12) Patent Application Publication
(10) Pub. No.: US 2006/0039111 A1
(43) Pub. Date: Feb. 23, 2006

(54) [HIGH-PERFORMANCE TWO-PHASE FLOW EVAPORATOR FOR HEAT DISSIPATION]

(75) Inventor: Lung-Wei Huang, TAIPEI (TW)

Correspondence Address: SHINE YING CO., LTD., 2F-4, NO. 148, SEC. 4, CHUNG HSIAO EAST ROAD, TAIPEI, TW

(73) Assignee: SHINE YING CO., LTD., HSINCHU CITY (TW)

(21) Appl. No.: 10/711,001

(22) Filed: Aug. 17, 2004

(51) Int. Cl. H05K 7/20

(52) U.S. Cl. 361/698; 361/709

(57) ABSTRACT

A high-performance two-phase flow evaporator is disclosed to include an electronic device, a casing, a heat sink provided at the top side of the casing and defining with the casing an enclosed chamber, a working fluid contained in the enclosed chamber, and a heat conducting member with top grooves formed of heat transfer material (k>80 W/m·K) in the bottom side of the casing in contact between the electronic device and the working fluid for transferring heat energy from the electronic device to the working fluid to heat the working fluid to give off steam so that heat energy is quickly dissipated from the electronic device into the outside open air through the heat sink and steam is quickly condensed into water upon heat exchange and returned to the heat conducting member by means of gravity.

### BACKGROUND OF INVENTION

1. Field of the Invention

The present invention relates generally to an evaporator and more particularly to a high-performance two-phase flow evaporator, which uses a heat conducting member to transfer heat energy from an electronic device to a working fluid in an enclosed chamber to heat the working fluid into vapor for quick dissipation of heat energy through a heat sink. The heat conducting member has grooves and/or fin in the top surface thereof to increase the contact area with the working fluid.

2. Description of the Related Art

Following fast development of computer technology, various apparatus have been disclosed for use in a computer to dissipate heat from the CPU of the computer. These heat dissipating apparatus include heat sink extruded from aluminum or copper, heat sink having a copper base and aluminum radiation fins, directional graphite heat plate, water cooling type heat dissipation member, heat pipe, combination heat pipe and heat sink, vapor chamber, two-phase flow evaporator. A two-phase flow evaporator is comprised of a metal container and radiation fins at the top side of the metal container. When in use, the bottom wall of the metal container is kept in contact with the electronic device, enabling heat energy to be transferred from the electronic device through the bottom wall to the inside of the metal container. The metal container has a capillary structure inside the surface metal, and the inside space of the metal container is drawn into a vacuum status. During transferring of heat energy from the electronic device to the metal container, a part of heat energy is transmitted to the whole metal container, and the rest of heat energy is transferred through the contact area between the electronic device and the metal container to the inside space of the metal container. Because the inside space of the metal container is maintained in a vacuum status, the working fluid in the capillary structure is caused to change the phase when hot, i.e., the working fluid is changed from fluid status into steam status, thereby producing air bubbles. Because the inside pressure of the air bubbles is relatively greater, the air bubbles move over the capillary structure to the space above the capillary structure, and then touch the cold top wall of the metal container. When touching the cold top wall of the metal container, heat energy is transferred from steam to the top wall of the metal container for dissipation into the outside open air by the radiation fins, and at the same time steam is condensed into fluid, which is transferred to the hot side by means of the capillary action of the capillary structure. Because reversible liquid-gas phase change absorbs or releases a big amount of heat energy, this design of two-phase flow evaporator has the characteristic of transferring heat energy rapidly at a big volume, keeping the working temperature of the electronic device stable.

Conventionally, a metal container for two-phase flow evaporator is made by welding two open metal casing together, or by welding two metal plates to the two ends of a metal column. Before welding or vacuum process, metal powder may be sintered to form the desired capillary structure. A two-phase flow evaporator made according to this design is heavy and expensive. When installing the retaining devices during assembly of a two-phase flow evaporator with an electronic device, the metal container may be deformed, thereby breaking the capillary structure. Damage to the capillary structure may lower heat transfer efficiency, or cause the working fluid unable to return to the hot side, thereby resulting in dry out. Further, because heat energy is transmitted from the electronic device to the whole area of the metal container, less amount of heat energy is transferred by phase change, the working efficiency of the two-phase flow evaporator is greatly reduced.

Therefore, it is desirable to provide a high-performance two-phase flow evaporator that eliminates the aforesaid drawbacks.

### SUMMARY OF INVENTION

The present invention has been accomplished under the circumstances in view. According to one aspect of the present invention, the high-performance two-phase flow evaporator comprises an electronic device, a casing, a heat sink provided at the top side of the casing and defining with the casing an enclosed chamber, a working fluid contained in the enclosed chamber, and a heat conducting member formed of heat transfer material (k>80 W/m·K) in the bottom side of the casing and disposed in contact between the electronic device and the working fluid for transferring heat energy from the electronic device to the working fluid to heat the working fluid to give off steam so that heat energy is quickly dissipated from the electronic device into the outside open air through the heat sink. According to another aspect of the present invention, the heat conducting member has grooves in the top surface in contact with the working fluid. The presence of the grooves in the top surface of the heat conducting member greatly increases the contact area of the heat conducting member with the working fluid and the working fluid holding space of the enclosed chamber. According to another aspect of the present invention, the heat conducting member of heat transfer material (k>80 W/m·K) effectively transfers heat energy from the electronic device to the working fluid to heat the working fluid into steam for exchanging heat with the heat sink. Upon contact of steam with the heat sink, steam is condensed into water, and condensed water immediately falls to the heat conducting member due to the effect of gravity. Therefore, fluid-vapor phase change is continuously cycled, enabling heat energy to be quickly transferred from the electronic device to the heat sink and then dissipated by the heat sink into the outside open air.

### BRIEF DESCRIPTION OF DRAWINGS

FIG. 1 is an elevational view of a high-performance two-phase flow evaporator according to the first embodiment of the present invention.

FIG. 2 is an exploded view of the high-performance two-phase flow evaporator according to the first embodiment of the present invention.

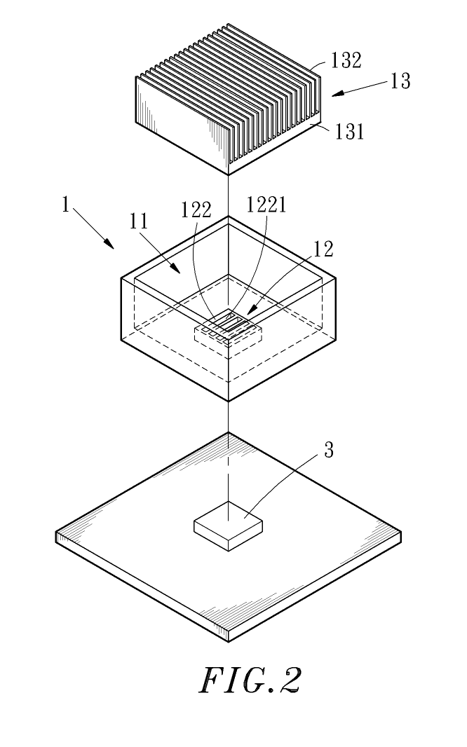

FIG. 3 is a schematic sectional side view of the first embodiment of the present invention, showing the high-performance two-phase flow evaporator in operation (I).

FIG. 4 is a schematic sectional side view of the first embodiment of the present invention, showing the high-performance two-phase flow evaporator in operation (II).

FIG. 5 is a sectional side view, showing the operation of a high-performance two-phase flow evaporator according to the second embodiment of the present invention.

FIG. 6 is a sectional side view showing the operation of a high-performance two-phase flow evaporator according to the third embodiment of the present invention.

### DETAILED DESCRIPTION

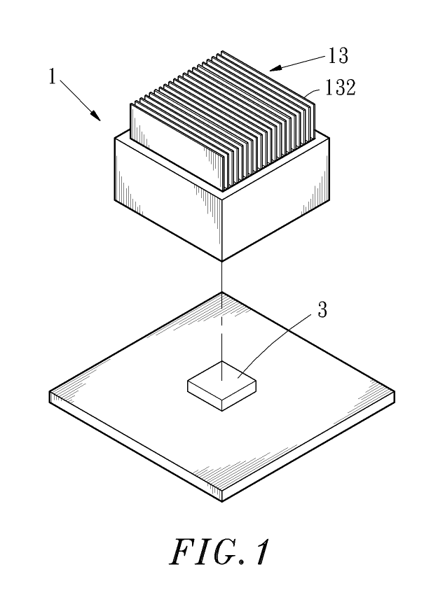

Referring to FIGS. 1˜3, a high-performance two-phase flow evaporator in accordance with the first embodiment of the present invention is shown comprised of a casing 1, a working fluid 2, and an electronic device 3.

The casing 1 can be stamped from a metal sheet member or injection-molded from plastics, defining therein an enclosed chamber 11 for accommodating the working fluid 2. The inside pressure of the enclosed chamber 11 is lower than the atmospheric pressure, i.e., the enclosed chamber 11 is maintained in a vacuum status. The casing 1 has a heat conducting member 12 formed of heat transfer material (k>80 W/m·K) in the bottom side. The heat conducting member 12 has a bottom contact surface 121 disposed in contact with the electronic device 3, a top heating surface 122 disposed in contact with the working fluid 2 in the enclosed chamber 11, and a plurality of grooves 1221 formed in the top heating surface 122. The top side of the enclosed chamber 11 is a metal heat sink 13. The heat sink 13 comprises a flat base 131 that closes the top side of the casing 1, and a plurality of radiating fins 132 upwardly extended from the top wall of the flat base 131 and arranged in parallel.

The working fluid 2 is held in the enclosed chamber 11 inside the casing 1. The working fluid 2 can be pure water, solvent containing oxygen (for example, alcohol, acetone), hydrocarbon, or their mixture.

The electronic device 3 is disposed in contact with the bottom contact surface 121 of the heat conducting member 12.

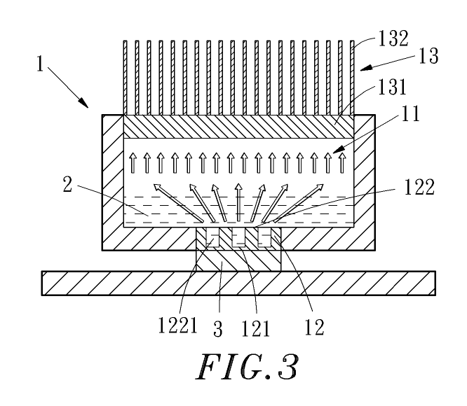

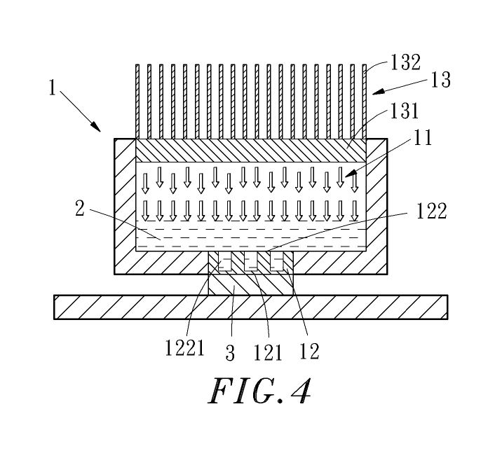

Referring to FIGS. 3 and 4, when the electronic device 3 is releasing heat energy during operation, the heat conducting member 12 absorbs heat energy from the electronic device 3 and transfers absorbed heat energy to the working fluid 2. Because the heat conducting member 12 has a plurality of water grooves 1221 formed in the top heating surface 122, the contact area between the heat conducting member 12 and the forking fluid 2 is relatively increased to accelerate the heating speed. Further, the presence of the water grooves 1221 in the top heating surface 122 of the heat conducting member 12 relatively increases the volume of the enclosed chamber 11 for holding the working fluid 2, i.e., a relatively greater volume of the working fluid 2 can be held in the enclosed chamber 11 to prevent the problem of dry out (the use of a wick structure in a conventional two-phase flow evaporator relatively reduces the working fluid holding space). Because the enclosed chamber 11 is controlled in a vacuum status to lower the boiling point of the working fluid 2, the working fluid 2 can quickly be heated to give out steam that flows toward the heat sink 13 (see hollow arrow signs in FIG. 3), enabling heat energy of steam to be absorbed by the flat base 131 and than transferred to the radiating fins 132, so that heat energy can be quickly dissipated into the outside open air. When heat energy was absorbed by the heat sink 13, steam is condensed into fluid status and returned to the bottom side of the enclosed space 11 due to the effect of gravity (see the hollow arrow signs in FIG. 4). When returned to fluid status, the working fluid 2 absorbs heat energy from the top heating surface 122, and is heated to give out steam again. This fluid-vapor phase alternation continues, and therefore heat energy is efficiently dissipated from the electronic device 3 into the outside open air through the heat sink 13 via the working fluid 2.

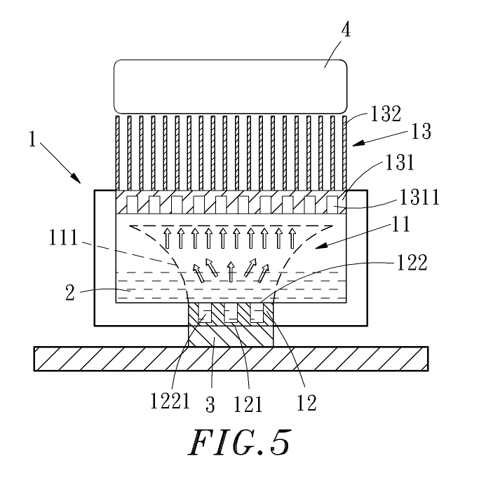

FIG. 5 shows a high-performance two-phase flow evaporator in accordance with the second embodiment of the present invention. According to this embodiment, the flat base 131 of the heat sink 13 has parallel grooves 1311 in the bottom surface. The presence of the grooves 1311 in the bottom surface of the flat base 131 greatly increases the heat exchange contact area to accelerate fluid-gas phase change speed. This embodiment further comprises an electric fan 4 provided at the top side of the radiation fins 132 and controlled to cause currents of air toward the radiation fins 132 to dissipates heat from the radiation fins 132 into the open air, and a steam guide 111 provided inside the enclosed chamber 11 and adapted to guide steam upwards from the working fluid 2 to the flat base 131 of the heat sink 13. Further, the water grooves 1221 can integrally be formed in the top heating surface 122 of the heat conducting member 12 during fabrication of the heat conducting member 12. Alternatively, the water grooves 1221 can be formed in the top heating surface 122 of the heat conducting member 12 by means of a lathing or welding technique. The grooves 1311 in the bottom surface of the flat base 131 of the heat sink 13 can be formed in the same manner as the formation of the water grooves 1221.

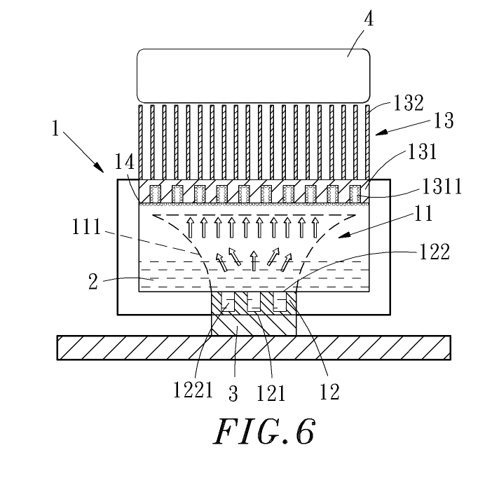

FIG. 6 shows a high-performance two-phase flow evaporator in accordance with the third embodiment of the present invention. According to this embodiment, the flat base 131 of the heat sink 13 has a wick structure 14 in the bottom side that increases heat exchange contact surface to enhance heat dissipation effect.

Further, grains or powder of ceramic or any of a variety of metal or non-metal materials that have a relatively higher density than the working fluid 2 may be added to the enclosed chamber 11 to accelerate heat transfer speed or to lift the water level of the working fluid 2 for enabling the heat conducting member 12 to be fully covered by the working fluid 2 without affecting the performance of the heat sink 13.

Further, the grooves 1221 can be independent recessed holes, recessed holes in communication with one another, or channel-like recessed holes. The grooves 1311 in the flat base 131 of the heat sink 13 can be made having any of a variety of shapes. The casing 1 can be made having a rectangular, conical, truncated cone, curved, or polygonal shape. The steam guide 111 can be made of metal or non-metal material.

In general, the high-performance two-phase flow evaporator of the present invention has the following features.

1. The invention provides a heat conducting member 12 of heat transfer material (k>80 W/m·K) and a metal heat sink 13 at the bottom and top sides of the casing 1, which may be formed of metal material or injection-molded from plastics, and grooves and/or fin 1221 are formed in the top heating surface 122 to increase the contact area of the heat conducting member 12 with the working fluid 2 and the working fluid holding space, preventing the problem of dry out.

2. Grooves or/and fin 1311 are formed in the bottom surface of the flat base 131 of the heat sink 13 to increase heat exchange contact surface, thereby improving heat dissipation efficiency.

3. Ceramic or metal grains/powder may be added to the enclosed chamber 11 to accelerate heat transfer speed or to lift the water level of the working fluid 2 for enabling the heat conducting member 12 to be fully covered by the working fluid 2 so that heat energy can efficiently be transferred to the working fluid 2 to heat the working fluid 2 into vapor.

Although particular embodiments of the invention have been described in detail for purposes of illustration, various modifications and enhancements may be made without departing from the spirit and scope of the invention. Accordingly, the invention is not to be limited except as by the appended claims.

1. A high-performance two-phase flow evaporator comprising:
an electronic device;
a casing mounted on said electronic device at a top side;
a metal heat sink provided at a top side of said casing and defining with said casing an enclosed chamber;
a working fluid contained in said enclosed chamber; and
a heat conducting member formed of heat transfer material (k>80 W/m·K) in a bottom wall of said casing;
wherein said heat conducting member has a bottom contact surface disposed in contact with said electronic device for absorbing heat from said electronic device during working of said electronic device, a top heating surface disposed in contact with said working fluid for transferring heat energy from said bottom contact surface to said working fluid, and at least one groove and/or fin formed in said top heating surface to increase the contact area of said heat conducting member with said working fluid.

2. The high-performance two-phase flow evaporator as claimed in claim 1, wherein said casing is made of a pure metal material.

3. The high-performance two-phase evaporator as claimed in claim 1, wherein said casing is made of a metal alloy.

4. The high-performance two-phase evaporator as claimed in claim 1, wherein said casing is injection-molded from plastics.

5. The high-performance two-phase evaporator as claimed in claim 1, wherein said working fluid is selected from a group of fluid materials including pure water, solvent containing oxygen, hydrocarbon, and their mixture.

6. The high-performance two-phase evaporator as claimed in claim 5, wherein said solvent containing oxygen includes alcohol, acetone.

7. The high-performance two-phase evaporator as claimed in claim 1, wherein said heat conducting member is an outer shell of said electronic device.

8. The high-performance two-phase evaporator as claimed in claim 1, wherein said electronic device is a CPU (central processing unit).

9. The high-performance two-phase evaporator as claimed in claim 1, wherein said metal heat sink comprises a flat base that covers a top side of said casing, and a plurality of radiation fins upwardly extended from a top or/and bottom wall of said flat base.

10. The high-performance two-phase flow evaporator as claimed in claim 9, wherein said flat base of said heat sink has at least one groove in a bottom surface thereof facing the inside of said enclosed chamber.

11. The high-performance two-phase flow evaporator as claimed in claim 1, further comprising metal and ceramic grains/powder put in said enclosed chamber.

12. The high-performance two-phase flow evaporator as claimed in claim 1, further comprising steam guide means provided inside said enclosed chamber and adapted to guide steam from said working fluid to said heat sink.
